(19) United States
(12) Patent Application Publication
(10) Pub. No.: US 2013/0106527 A1
(43) Pub. Date: May 2, 2013

(54) VARIABLE CAPACITANCE MEMS VARACTOR ARRAY METHOD & APPARATUS

(71) Applicant: TEXAS INSTRUMENTS INCORPORATED, Dallas, TX (US)

(72) Inventors: Arun K. Gupta, Dallas, TX (US); William C. McDonald, Allen, TX (US)

(73) Assignee: TEXAS INSTRUMENTS INCORPORATED, Dallas, TX (US)

(21) Appl. No.: 13/661,919

(22) Filed: Oct. 26, 2012

Related U.S. Application Data
(60) Provisional application No. 61/551,616, filed on Oct. 26, 2011.

(51) Int. Cl. H03H 7/38; H01G 5/16

(52) U.S. Cl. 333/33; 361/290

(57) ABSTRACT

Impedance between an antenna and a power amplifier in a cell phone is dynamically matched by selectively increasing the potential difference between a bias electrode and a top plate to move the top plate to a down position for a number of varactors needed to change the capacitance and bring about the match. Each varactor has a capacitor bottom plate formed on the substrate to include the bias electrode, a ground electrode and an RF signal line electrode. A capacitor top plate is suspended by mechanical spring action above the bottom plate for movement between an up position and a down position relative to dielectric material covering the bottom plate. The potential difference applied between the bias electrode and the top plate can be selectively increased to overcome the spring action and move the top plate to the down position, shunting an RF signal applied at the RF signal line electrode to ground through the top plate.

This application claims the benefit of Provisional Application No. 61/551,616, filed Oct. 26, 2011, the entirety of which is hereby incorporated by reference.

### BACKGROUND

For many electronic circuit applications, it is desirable to have a capacitor element with variable capacitance, also known as a varactor. Current implementations of variable capacitance include varactor diodes and switched capacitors. Varactor diodes are inherently non-linear and introduce noise into the circuit. They also have a very small tuning range. Switched capacitors rely on transistors to switch in fixed capacitance. However, the switch introduces loss at high frequency, and the switch can also add noise. Furthermore, both solutions have limited power handling ability.

One potential application that would require such a varactor is dynamic impedance matching between the antenna and the power amplifier in cellular phone front ends. Since the impedance of the antenna changes depending on its environment (next to the head, in a pocket, or on the table), a dynamic matching network is needed to maintain a good match. This requires a digital varactor tuning element that adds little insertion loss and can handle the 30 dBm transmit power coming from the power amplifier. This is but one example application; others exist as well.

A varactor with a large and linear tuning range, fine tuning resolution, high power handling, low loss (high Q factor), and low noise is desired. It is also desirable to have a digitally controllable varactor to interface with digital control systems.

### SUMMARY

In one aspect, a variable capacitance MEMS (microelectromechanical system) varactor array is provided.

In another aspect, a method of varying capacitance is provided.

In another aspect, apparatus and methods are provided for dynamic impedance matching between an antenna and a power amplifier in a cellular front end.

In an example embodiment, a variable capacitance MEMS varactor is provided. The varactor has a capacitor bottom plate formed on a substrate. The bottom plate includes a bias electrode, a ground electrode and an RF signal line electrode. Dielectric material is formed over the capacitor bottom plate, including over at least over the ground electrode and RF signal electrode. A capacitor top plate is suspended by mechanical spring action above the bottom plate for movement between an up position and a down position relative to the dielectric material and bottom plate. A potential difference applied between the bias electrode and the top plate can be selectively increased to overcome the spring action and move the top plate to the down position, shunting an RF signal applied at the RF signal line electrode to ground through the top plate.

In an example, there are spaced first and second bias electrodes, with the ground and RF signal line electrodes located in laterally spaced positions between the first and second bias electrodes.

In an example, the varactor is electrically connected in an array of like varactors having their respective bottom plates formed on the same substrate. The RF signal line electrodes are electrically connected to form an RF signal transmission line and the ground electrodes of the multiple like varactors are electrically connected to form a common ground line.

In an example, the array has two parallel groupings of varactors; and the RF signal transmission line and ground line each has two parallel branches connecting the respective varactor electrodes of each grouping, with the two ground line branches run outwardly of the two RF transmission line branches. Electrical circuitry is provided for applying the potential difference between the at least one bias electrode and the top plate.

In an example method for dynamically matching impedance between an antenna and a power amplifier in a cell phone, an RF signal is applied on the RF transmission line electrically connecting the respective varactor RF signal line electrodes in the array. A desired change in RF signal to ground capacitance is determined for matching the impedance; and the potential difference between the bias electrode and the top plate is selectively increased to move the top plate to the down position for the number of varactors needed to effect the desired change in capacitance.

### BRIEF DESCRIPTION OF THE DRAWINGS

FIG. 1 illustrates an example varactor array.

FIG. 2A is a cross-sectional view of a coplanar transmission line. FIG. 2B is a top view showing the transmission line branching into several parallel fingers.

FIG. 3A is a cross-sectional view of a modified arrangement, wherein the movable plate is directly connected to RF GND. FIG. 3B is a top view of the modified arrangement.

### DETAILED DESCRIPTION OF EXAMPLE EMBODIMENTS

The entirety of application Ser. No. 13/614,571 filed Sep. 13, 2012, which deals with related subject matter is hereby incorporated by reference.

An example implementation takes the form of an array of digital MEMS varactors. Each varactor consists of a moveable metal top plate that is suspended in air above a fixed metal bottom plate with a mechanical spring suspension. This forms an air dielectric parallel plate capacitor. The bottom plate may be split up into bias electrodes and RF electrodes, and each electrode is covered with a thin layer of solid dielectric.

As the DC potential between the bottom electrodes and the top plate increases, the resultant electric field produces an attractive force. Since the top plate is suspended on a mechanical spring, this attractive force causes the top plate to move toward the bottom electrodes. This movement changes the capacitance between the top plate and the RF signal electrodes, since capacitance is inversely dependent upon gap size.

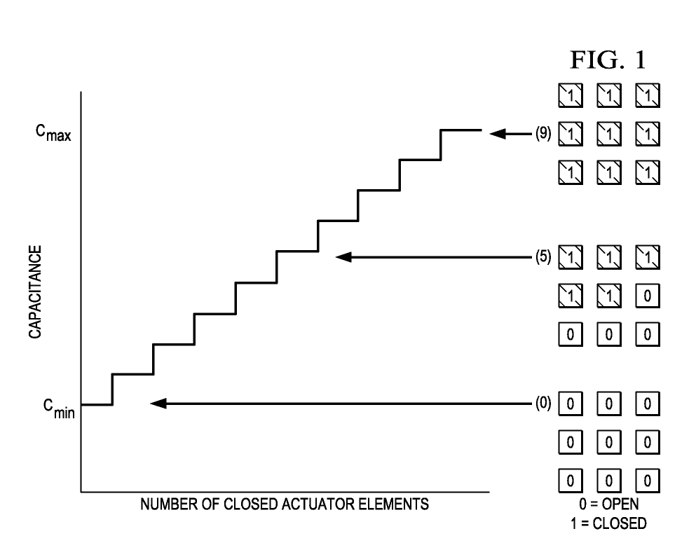

To implement digital control, each varactor would have an “on” state and an “off” state, respectively corresponding with a high capacitance value in which the top plate is touched down onto the dielectric that covers the bottom electrodes, and a low capacitance value in which the top plate is as far away from the bottom electrodes as is allowed by the mechanical suspension. Thus, with a parallel array of these varactors, a control chip could turn some capacitors on and leave some off, yielding a range of capacitance values with digital control. FIG. 1 shows an example with an array of 9 varactors.

In the array implementation, the bottom RF signal electrodes of each varactor would be connected together to form a transmission line. The top plates would remain unconnected for reasons of manufacturability and tuning resolution. The varactors could be arrayed in a straight line above a single transmission line, or the transmission line could branch into several parallel fingers, for reduced series resistance.

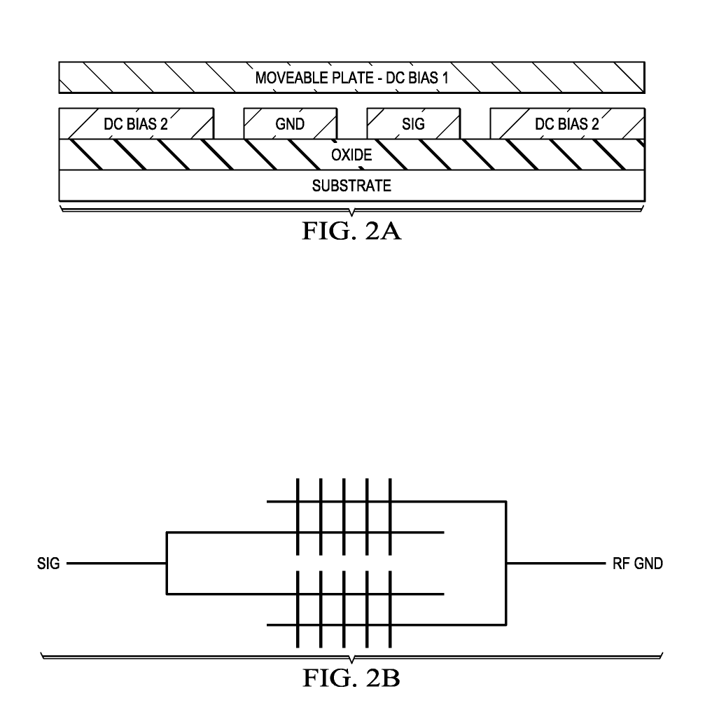

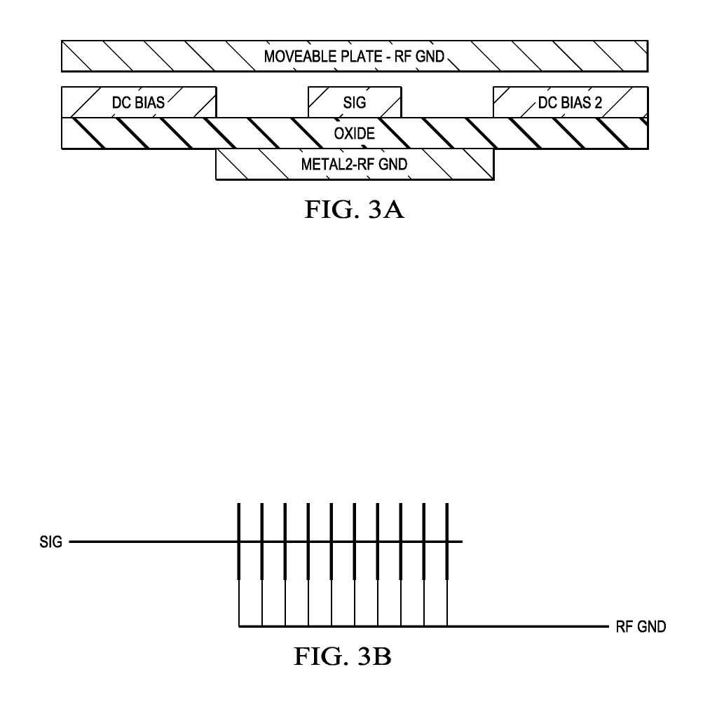

Example embodiments are shown in FIGS. 2A-2B and 3A-3B.

FIG. 2A shows a coplanar transmission line. As the moveable plate is pulled down by the electric field resulting from the potential difference between DC Bias 1 and DC Bias 2, an RF signal on the SIG line will shunt through the movable plate to GND. This embodiment has two parallel fingers, as seen in FIG. 2B. In FIG. 2B, the moveable plates are indicated by the vertical lines in the center; and the transmission line routing is indicated by the horizontal lines and the vertical lines at the right and left sides.

FIG. 3A shows a modification wherein the movable plate is directly connected to RF GND. This way, the signal shunts directly from SIG to RF GND in the top plate. The implication of this is that while the RF signal in FIG. 2A travels through two series capacitors on its way to RF GND, the signal in FIG. 3A only travels through one capacitor. The transmission line could be coplanar or microstrip. The illustrated embodiment has just one finger.

In FIG. 3B, the moveable plates are indicated by the thick vertical lines in the center; and the transmission line routing is indicated by the horizontal lines and the thin vertical lines below the thick vertical lines.

Other embodiments may have DC bias electrodes not forming part of the capacitor bottom plate. Rather, in such embodiments the top plate may be biased with a DC voltage, creating a DC potential between the top plate and the RF signal electrodes that form the bottom plate.

Other embodiments incorporating the same principles may be realized.

What is claimed is:

1. A variable capacitance MEMS varactor, comprising
a capacitor bottom plate formed on a substrate, the bottom plate including a bias electrode, a ground electrode and an RF signal line electrode;
dielectric material formed over the capacitor bottom plate, including over at least over the ground electrode and RF signal electrode;
a capacitor top plate suspended by mechanical spring action above the bottom plate for movement between an up position and a down position relative to the dielectric material and bottom plate;
wherein a potential difference applied between the bias electrode and the top plate can be selectively increased to overcome the spring action and move the top plate to the down position, shunting an RF signal applied at the RF signal line electrode to ground through the top plate.

2. The varactor of claim 1, wherein the bias electrode comprises spaced first and second bias electrodes, and the ground and RF signal line electrodes are located in laterally spaced positions between the first and second bias electrodes.

3. The varactor of claim 2, wherein the varactor is electrically connected in an array of multiple like varactors having respective bottom plates formed on the substrate; and the RF signal line electrodes of the multiple like varactors are electrically connected to form an RF signal transmission line.

4. The varactor of claim 3, wherein the ground electrodes of the multiple like varactors are electrically connected to form a common ground line.

5. The varactor of claim 4, wherein the array comprises two parallel groupings of like varactors; the RF signal transmission line includes two parallel branches respectively connecting the RF signal line electrodes of the varactors of each grouping; and the ground line includes two parallel branches respectively connecting the ground electrodes of the varactors of each grouping.

6. The varactor of claim 5, wherein the two ground line branches run outwardly of the two RF transmission line branches.

7. The varactor of claim 1, wherein the varactor is electrically connected in an array of multiple like varactors having respective bottom plates formed on the substrate; and the RF signal line electrodes of the multiple like varactors are electrically connected to form an RF signal transmission line.

8. The varactor of claim 7, wherein the array comprises two parallel groupings of like varactors; the RF signal transmission line includes two parallel branches respectively connecting the RF signal line electrodes of the varactors of each grouping; and the ground line includes two parallel branches respectively connecting the ground electrodes of the varactors of each grouping.

9. The varactor of claim 8, wherein the two ground line branches run outwardly of the two RF transmission line branches.

10. The varactor of claim 9, wherein the ground electrodes of the multiple like varactors are electrically connected to form a common ground line.

11. The varactor of claim 1, wherein the varactor is electrically connected in an array of multiple like varactors having respective bottom plates formed on the substrate; and the ground electrodes of the multiple like varactors are electrically connected to form a common ground line.

12. Apparatus for dynamically matching impedance between an antenna and a power amplifier in a cell phone, comprising:
an array of MEMS varactors, each varactor comprising:
a capacitor bottom plate formed on a substrate, the bottom plate including a bias electrode, a ground electrode and an RF signal line electrode;
dielectric material formed over the capacitor bottom plate, including over at least over the ground electrode and RF signal electrode; and
a capacitor top plate suspended by mechanical spring action above the bottom plate for movement between an up position and a down position relative to the dielectric material and bottom plate;
wherein a potential difference applied between the bias electrode and the top plate can be selectively increased to overcome the spring action and move the top plate to the down position, shunting an RF signal applied at the RF signal line electrode to ground through the top plate;
an RF signal transmission line electrically connecting the respective RF signal line electrodes of varactors; and
electrical circuitry applying the potential difference between the at least one bias electrode and the top plate.

13. The apparatus of claim 12, wherein each varactor bias electrode comprises spaced first and second bias electrodes, and wherein the ground and RF signal line electrodes of each varactor are located in laterally spaced positions between that varactor's first and second bias electrodes.

14. The apparatus of claim 13, further comprising a common ground line connecting the respective ground electrodes of the varactors.

15. The apparatus of claim 14, wherein the array comprises two parallel groupings of varactors; the RF signal transmission line includes two parallel branches respectively connecting the RF signal line electrodes of the varactors of each grouping; and the ground line includes two parallel branches respectively connecting the ground electrodes of the varactors of each grouping.

16. The apparatus of claim 15, wherein the two ground line branches run outwardly of the two RF transmission line branches.

17. The apparatus of claim 12, further comprising a common ground line connecting the respective ground electrodes of the varactors.

18. The apparatus of claim 12, wherein the array comprises two parallel groupings of varactors; the RF signal transmission line includes two parallel branches respectively connecting the RF signal line electrodes of the varactors of each grouping; and the ground line includes two parallel branches respectively connecting the ground electrodes of the varactors of each grouping.

19. The apparatus of claim 18, wherein the two ground line branches run outwardly of the two RF transmission line branches.

20. A method for dynamically matching impedance between an antenna and a power amplifier in a cell phone, comprising:
providing an array of MEMS varactors, each varactor comprising:
a capacitor bottom plate formed on a substrate, the bottom plate including a bias electrode, a ground electrode and an RF signal line electrode;
dielectric material formed over the capacitor bottom plate, including over at least over the ground electrode and RF signal electrode; and
a capacitor top plate suspended by mechanical spring action above the bottom plate for movement between an up position and a down position relative to the dielectric material and bottom plate;
wherein a potential difference applied between the bias electrode and the top plate can be selectively increased to overcome the spring action and move the top plate to the down position, shunting an RF signal applied at the RF signal line electrode to ground through the top plate;
applying an RF signal on a transmission line electrically connecting the respective RF signal line electrodes of varactors;
determining a desired change in capacitance for the RF signal to ground for matching the impedance; and
selectively increasing the potential difference between the bias electrode and the top plate to move the top plate to the down position for a number of varactors that will effect the desired change in capacitance.
